(19) United States
(12) Patent Application Publication
(10) Pub. No.: US 2026/0262526 A1
(43) Pub. Date: Sep. 3, 2026

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Antonio BELLIZZI, Cologno Monzese (IT); Samuele ZALAFFI, Salsomaggiore (IT); Alessandro ` MELLINA GOTTARDO, Milano (IT)

(73) Assignee: STMicroelectronics International N.V., Geneva (CH)

(21) Appl. No.: 19/550,832

(22) Filed: Feb. 26, 2026

(30) Foreign Application Priority Data
Feb. 28, 2025 (IT) 102025000004167

(51) Int. Cl. H10W 72/00; H10W 72/60; H10W 90/00; H10W 90/28

(52) U.S. Cl. CPC H10W 72/01615; H10W 72/634; H10W 72/653; H10W 72/655; H10W 90/28; H10W 90/762; H10W 90/766; H10W 72/886; H10W 90/736

(57) ABSTRACT

A first semiconductor die is arranged at a die pad of a substrate including electrically conductive leads arranged sidewise of the die pad. An electrically conductive clip extends bridge-like between the first semiconductor die and at least one lead out of the electrically conductive leads to provide electrical coupling therebetween. The electrically conductive clip is applied onto the first semiconductor die with a first surface of the electrically conductive clip facing the first semiconductor die. An electrically insulating layer is present at a second surface of the electrically conductive clip opposite the first surface. A second semiconductor die is arranged on the electrically insulating layer. Electrical insulation of the second semiconductor die from the electrically conductive clip is facilitated by the electrically insulating layer formed at the second surface of the electrically conductive clip.

### PRIORITY CLAIM

This application claims the priority benefit of Italian Application for Patent No. 102025000004167 filed on February 28, 2025, the content of which is hereby incorporated by reference in its entirety to the maximum extent allowable by law.

### TECHNICAL FIELD

The description relates to manufacturing semiconductor devices.

Solutions as described herein can be applied to so-called “system-in-package” devices for automotive products, for instance.

### BACKGROUND

In power semiconductor devices, the current transferred from the high-power section to the output pads of the device can be significant. Clips (or ribbons) are used for that purpose in the place of wires.

In devices comprising more than one semiconductor die, a power die may be driven by a controller die provided in the same package with the power die. Such devices are oftentimes referred to as “system-in-package” (SiP) devices.

In certain SiP devices, the semiconductor dice (controller die and power die) and the electrically conductive clip (provided with a substantially flat shape) may be arranged in a stacked configuration onto a substrate (a leadframe, for instance).

In such stacked configuration, a semiconductor die (a controller, for instance) may be arranged on the electrically conductive clip that provides (power) electrical coupling between the substrate and another semiconductor die (a power die, for instance).

The semiconductor die arranged onto the electrically conductive clip is electrically insulated therefrom via an electrically insulating die-attach material used to mount (attach) the semiconductor die onto the electrically conductive clip.

However, undesired short circuits between the clip and the semiconductor die mounted thereon have been observed, which cause failure or rejection of the device.

Reference is also made to United States Patent Application Publication Nos. 2024/0203836, 2014/0117523, 2016/0307830, 2022/0367328 and 2016/0197066, and United States Patent No. 10,115,645, all incorporated herein by reference, which provide background information in the related technological area.

There is a need in the art to address the issues discussed in the foregoing.

### SUMMARY

One or more embodiments relate to a method.

One or more embodiments relate to a corresponding semiconductor device.

Solutions as described herein involve arranging two (or more) semiconductor dice and an electrically conductive clip in a stacked configuration, with a semiconductor die arranged onto the electrically conductive clip.

In solutions as described herein, electrical insulation of the electrically conductive clip from the semiconductor die arranged thereon is facilitated via an electrically insulating layer provided therebetween.

In solutions as described herein, the electrically insulating layer is provided in addition to (electrically insulating) die-attach material conventionally used for attaching the semiconductor die to the electrically conductive clip.

In solutions as described herein, the electrically insulating layer may have an area that is larger than the area of the semiconductor die.

In solutions as described herein, the electrically insulating layer may advantageously be used to provide a substantially flat die-mounting surface.

### BRIEF DESCRIPTION OF THE DRAWINGS

One or more embodiments will now be described, by way of example only, with reference to the annexed figures, wherein:

FIGS. 1 and 2 are respectively a plan view and a cross-sectional view (along line II-II of FIG. 1) illustrative of the structure of a semiconductor device;

FIG. 3 is an enlarged view of the portion of FIG. 2 indicated by the arrow III;

FIGS. 4 and 5 are respectively a plan view and a cross-sectional view (along line V-V of FIG. 4) illustrative of the structure of a semiconductor device;

FIGS. 6A and 6B are cross-sectional views illustrative of processing steps; and

FIG. 7 is an enlarged view of the portion of FIG. 6B indicated by the arrow VII.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

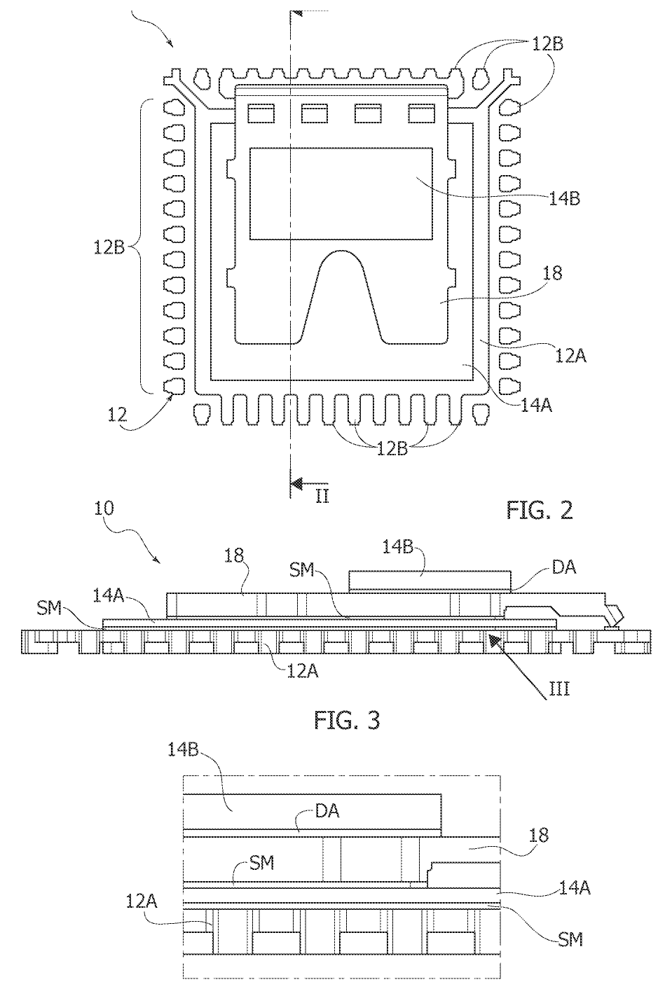

FIGS. 1 and 2 are respectively a plan view and a cross-sectional view (along line II-II of FIG. 1) illustrative of the structure of a (integrated circuit, IC) power semiconductor device 10 comprising two semiconductor (Si, SiC, GaN, for instance) dice 14A, 14B stacked over a leadframe 12.

The designation “leadframe” (or “lead frame”) is currently used (see, for instance the USPC Consolidated Glossary of the United States Patent and Trademark Office) to indicate a metal frame that provides support for an integrated circuit chip or die (the terms die/dice and chip/chips are herein regarded as synonymous) as well as electrical leads 12B to interconnect the integrated circuit in the die to other electrical components or contacts.

Essentially, a leadframe 12 comprises an array of electrically-conductive formations (or leads) 12B that from an outline location extend inwardly in the direction of a semiconductor die (such as the semiconductor dice 14A or 14B, for instance) thus forming an array of electrically-conductive formations from a die pad 12A configured to have (at least) one semiconductor die attached thereon.

In certain cases, a leadframe 12 can be of the pre-molded type, that is a type of leadframe comprising a sculptured metal (copper, for instance) structure formed by etching a metal sheet and comprising empty spaces that are filled by a resin “pre-molded” on the sculptured metal structure.

In more detail, a power semiconductor device 10 as illustrated in FIGS. 1 and 2 comprise: a first (power) semiconductor die 14A arranged at a surface of a die pad 12A in a leadframe 12 via die-attach material SM (a solder paste or a die-attach glue, for instance); an electrically conductive clip 18 arranged onto the first semiconductor die 14A, bridge-like between the first semiconductor die 14A and selected one or more (power) leads 12B in the array of electrically conductive leads 12B to provide electrical coupling therebetween; and a second semiconductor die 14B (a driver or controller die, for instance) arranged onto the electrically conductive clip 18.

In a power semiconductor device 10 as illustrated in the figures, the current transferred from the power semiconductor die 14A to the (power) output pads 12B (that is, the leads 12B in the leadframe 12) of the device 10 can be significant. Electrically conductive clips 18 are thus used for that purpose in the place of wires. Wires can still be used to provide electrical coupling to the (low-power) second semiconductor die 14B (a controller die, for instance) or to provide electrical coupling between the first 14A and the second 14B semiconductor die.

Clips 18 as considered herein may be formed via stamping or punching of a sheet of metallic material (copper, for instance).

As illustrated, the electrically conductive clip 18 is attached onto the first semiconductor die 14A. Solder material SM may be provided at the top/front surface of the first semiconductor die 14A to facilitate forming electrical coupling between the electrically conductive clip 18 and die bonding pads (that is, electrical contacts for the IC embedded in the die) at the front/top surface of the first semiconductor die 14A (the die bonding pads are not illustrated in the figures for simplicity).

FIG. 3 is an enlarged view of the portion of FIG. 2 indicated by the arrow III illustrative of details of a stacked arrangement of the semiconductor dice 14A, 14B and the electrically conductive clip 18 as described in the foregoing.

Those skilled in the art may appreciate that such stacked arrangement may be desirable in so far as it facilitates reducing dimension/size of the device (compared to a device comprising semiconductor dice arranged at respective die pads, for instance).

To that effect, the second semiconductor die 14B is arranged on the electrically conductive clip 18 via electrically insulating die-attach material DA; electrically insulating die-attach material DA is provided in order to electrically insulate the second semiconductor die 14B from the electrically conductive clip 18.

The electrically insulating die-attach material DA may be a die-attach film. Conventionally, a die-attach film DA is provided at wafer level, prior to singulating the wafer to obtain a plurality of semiconductor dice (such as the second semiconductor die 14B). That is, a semiconductor wafer is provided comprising a plurality of wafer portions that, subsequently to singulation of the wafer, provide respective (singulated) semiconductor dice 14B. Prior to singulation, a die-attach film is laminated onto a surface of the semiconductor wafer (thus concurrently providing the die-attach film to the plurality of wafer portions in the wafer).

A plurality of semiconductor dice (such as the second semiconductor die 14B illustrated in the figures) having a portion of the die-attach film at a surface thereof is obtained in response to the singulation of the semiconductor wafer having the die-attach film laminated thereon. Subsequently, each semiconductor die 14B is attached onto an electrically conductive clip 18 in respective devices 10, with the (portion of the) die-attach film DA in contact with the electrically conductive clip 18.

It is noted that the die-attach film DA at the surface of each semiconductor die 14B (that is, the portion of the die-attach film laminated at the surface of the wafer) has notionally the same area of the semiconductor die 14B in response to the fact that the wafer and the die-attach film laminated thereon are singulated/partitioned in a same singulation step.

A die-attach material DA as described in the foregoing (a die-attach film having the same area of the die, for instance) has been observed to provide inadequate electrical insulation of the second semiconductor die 14B from the electrically conductive clip 18. In fact, small fragments of semiconductor material may undesirably detach form the body of the second semiconductor die 14B and contact the electrically conductive clip 18. Such fragments may form in response to the singulation of the semiconductor wafer (performed by cutting the wafer with a blade, for instance) at the periphery of the semiconductor die (a phenomenon oftentimes referred to as “chipping”). Such fragments may electrically couple the second semiconductor die 14B to the electrically conductive clip 18 thus causing failure (or rejection) of the device 10.

Solutions as described herein involve arranging two (or more) semiconductor dice 14A, 14B and an electrically conductive clip 18 in a stacked configuration.

In solutions as described herein, electrical insulation of the electrically conductive clip 18 from the semiconductor die arranged thereon is facilitated via an electrically insulating layer provided therebetween.

In solutions as described herein, the semiconductor die 14B may be attached onto the electrically insulating layer via (electrically insulating) die-attach material DA.

In solutions as described herein, the electrically insulating layer may have an area that is larger than the area of the semiconductor die.

In solutions as described herein, the electrically insulating layer may advantageously be used to provide a substantially flat die-mounting surface onto which the semiconductor die 14B is arranged.

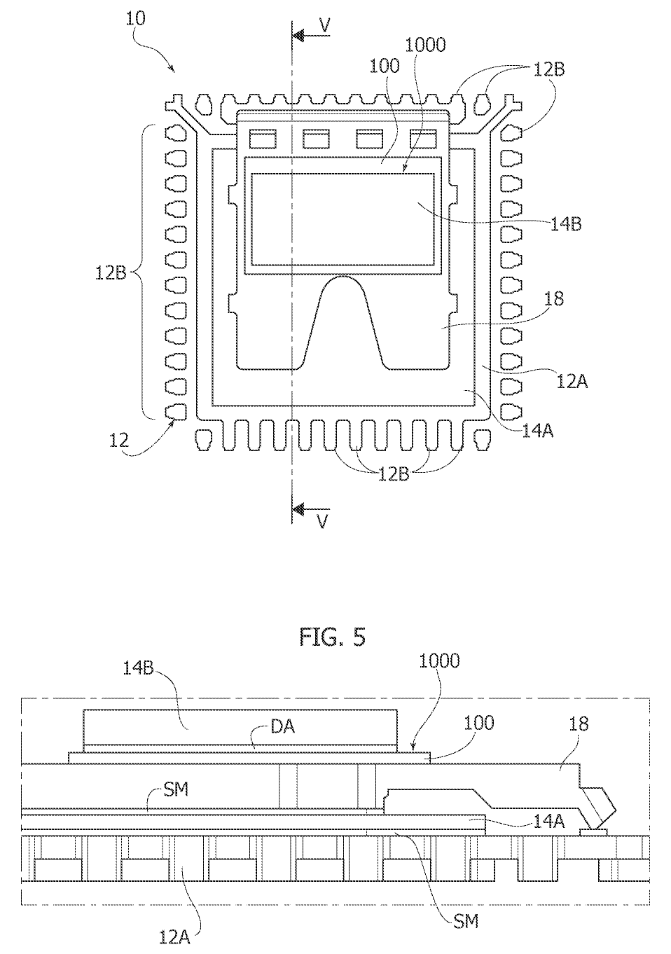

FIGS. 4 and 5 are respectively a plan view and a cross-sectional view (along line V-V of FIG. 4) illustrative of the structure of a semiconductor device 10 according to embodiments of the present description.

Similarly to what has been described previously, the semiconductor device 10 comprises: a first semiconductor die 14A (a power die, for instance) arranged at a die pad 12A in a substrate 12 (a leadframe, for instance) comprising arrays of electrically conductive leads 12B arranged sidewise of the die pad 12A; and an electrically conductive clip 18 applied bridge-like between the first semiconductor die 14A arranged at the die pad 12A and selected leads 12B of the arrays of electrically conductive leads 12B arranged sidewise of the die pad 12A to provide electrical coupling therebetween.

It is noted that in current manufacturing processes of semiconductor devices, plural devices are manufactured concurrently to be separated into single individual device in a final singulation; the leadframe 12 illustrated in the figures may be a portion of a leadframe reel or panel comprising a plurality of (individual) leadframes 12 as illustrated in FIGS. 4 and 5, for instance.

For simplicity and ease of explanation, the following description will refer to manufacturing a single device.

As illustrated, the electrically conductive clip 18 is arranged onto the first semiconductor die 14A with a first surface thereof facing the first semiconductor die 14A; the electrically conductive clip 18 is electrically coupled to the die bonding pads at the top/front surface of the first semiconductor die 14A via solder material SM provided thereon.

According to solutions as described herein, an electrically insulating layer 100 may be formed at the top/front surface of the electrically conductive clip 18 or, said otherwise, at a second surface of the electrically conductive clip 18 opposite the first surface. The electrically insulating layer 100 is preferably not made of a hard or rigid material but rather is made of a compressible or flexible material (for example, a polymeric material).

A second semiconductor die 14B (a driver/controller die, for instance) is arranged onto the electrically insulating layer 100 formed at the top/front surface of the electrically conductive clip 18.

The electrically insulating layer 100 is provided in addition to an (electrically insulating) die-attach film DA possibly provided at a surface of the second semiconductor die 14B. Such a (further) electrically insulating layer 100 facilitates providing adequate electrical insulation of the second semiconductor die 14B from the electrically conductive clip 18 onto which the second semiconductor die 14B is arranged.

In one or more embodiments, the electrically insulating layer 100 may be formed by dispensing electrically insulating material on the second (top/front) surface of the clip 18 via additive manufacturing techniques.

Suitable materials for the electrically insulating layer 100 comprise, for instance, an acrylic, epoxy or polyester based paste.

Advantageously, a laser induced forward transfer (LIFT) technique may be used to form the electrically insulating layer 100.

Laser induced forward transfer denotes a deposition process where material from a donor tape or sheet is transferred to an acceptor substrate (here, the second surface of the clip 18) facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

According to certain embodiments of the present description, the electrically insulating layer 100 may be formed on the second (top/front) surface of the electrically conductive clip 18 (already) arranged onto the first semiconductor die 14A.

According to certain embodiments of the present description, the electrically insulating layer 100 may be formed on the second (top/front) surface of the electrically conductive clip 18 prior to arranging the electrically conductive clip 18 onto the first semiconductor die 14A. A suitable electrically insulating material for the electrically insulating layer 100 may comprise materials that are not negatively affected by (that is, resistant to) the relatively high temperatures of a reflow step, possibly performed when the electrically conductive clip 18 is attached onto the first semiconductor die 14A via solder material SM, for instance.

With reference to FIG. 5, the second semiconductor die 14B may be arranged onto the electrically insulating layer 100 via die-attach material DA (an adhesive die-attach film as described in the foregoing, for instance) provided at a die-attach surface of the second semiconductor die 14B, that is, the surface of the second semiconductor die 14B configured to be attached onto the electrically insulating layer 100.

As illustrated in the figures, the die-attach material DA (a die-attach film, for instance) may extend over an area notionally equal to the area of the second semiconductor die 14B. Advantageously, the electrically insulating layer 100 may have a layer area larger than the area of the second semiconductor die 14B (and, consequently, larger than the area of the die-attach film DA provided at the surface of the second semiconductor die 14B). This may be advantageous in so far as it counters formation of undesired short circuits (or, more, generally, electrical coupling) between the second semiconductor die 14B and the electrically conductive clip 18 also in the case of detachment of fragments of semiconductor material from the second semiconductor die 14B that may occur in response to a singulation step (“chipping”).

In fact, as illustrated in FIG. 4, for instance, the second semiconductor die 14B may be mounted at a central region of the top/front surface of the electrically insulating layer 100 (at the top/front or die-mounting surface 100A thereof), with a peripheral region 1000 of the die-mounting surface 100A around the central region that is left uncovered by the second semiconductor die 14B.

Contact between fragments of semiconductor material that may detach from the second semiconductor die 14B and the electrically conductive clip 18 is thus countered by the peripheral region 1000 of the electrically insulating layer 100 which provides a sort of clearance or safety region.

According to embodiments of the present description, solutions as described herein may advantageously be applied in cases wherein the electrically conductive clip 18 has a warped/deformed shape. As mentioned, clip 18 may be provided by stamping/punching of a metallic (copper, for instance) sheet and a warped/deformed shape may result in response to such manufacturing steps.

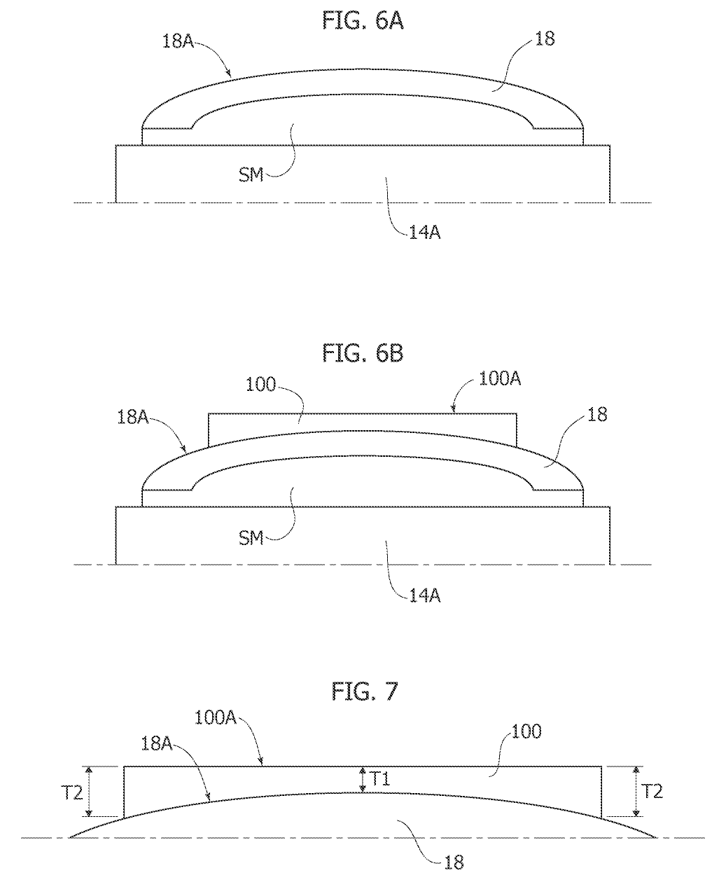

FIG. 6A is illustrative of a deformed/warped electrically conductive clip 18 applied (via solder material SM) onto a semiconductor die 14A (the first, power, semiconductor die 14A illustrated in FIGS. 4 and 5, for instance).

As illustrated, the top/front surface 18A of the electrically conductive clip 18 is curved in response to the fact that the electrically conductive clip 18 is warped.

In one or more embodiments of the present description, the electrically insulating layer 100 may be formed onto the electrically conductive clip 18 with a varying thickness to compensate the warped surface 18A of the electrically conductive clip 18.

FIGS. 6B and 7 (wherein FIG. 7 is an enlarged view of the portion of FIG. 6B indicated by the arrow VII) are illustrative of such embodiments.

As illustrated, the electrically insulating layer 100 may be formed (via an additive manufacturing technique such as LIFT, for instance) with a non-uniform, that is, varying, thickness in order to compensate for the deformed surface 18A of the electrically conductive clip 18.

With reference to FIG. 7, the electrically conductive clip 18 may have a convex (dome-like) top/front surface 18A; correspondingly, the electrically insulating layer 100 may be formed with a thickness that varies between a minimum thickness T1 (at the central region of the convex surface 18A of the clip 18) and a maximum thickness T2 (at distal regions of the convex surface 18A of the clip 18) so that the top/front surface 100A of the electrically insulating layer 100 (that is, the die-mounting surface 100A configured to have the second semiconductor die 14B arranged thereon) is substantially flat.

Having a second semiconductor die 14B arranged on a (substantially) flat die-mounting surface 100A may be advantageous in so far as it facilitates adherence/contact of the die-attach material possibly provided at a (substantially flat) surface of a semiconductor die to the (substantially flat) die-mounting surface 100A provided by the electrically insulating layer 100.

Moreover, a flat die-mounting surface 100A causes the die bonding pads at the top/front (active) surface of the second semiconductor die 14B to lie at a same height, thus facilitating a subsequent wire bonding step, wherein electrically conductive wires are provided in electrical contact with said die bonding pads.

It is noted that, despite an electrically conductive clip 18 having a convex top/front surface 18A is illustrated in the figures, solutions as described herein may similarly be applied to the case of an electrically conductive clip 18 having a concave (scoop-like) top/front surface 18A

In one or more embodiments, the degree of warpage of the electrically conductive clip 18 may be detected/measured (via optical sensors, for instance) and the electrically insulating layer 100 may be formed with a layer thickness that varies as a function of the detected/measured warpage.

In one or more embodiments, average values of the warpage of an electrically conductive clip 18 may be used to form an electrically insulating layer 100 with a varying thickness that provides a substantially flat die-mounting surface 100A. In fact, it has been observed that electrically conductive clips 18 manufactured via stamping or punching exhibit a similar degree of warpage and forming an electrically conductive layer with a thickness that varies as a function of an “average warpage” of the clips leads to satisfactory results (that is, to substantially flat die-mounting surface 100A).

In summary, in solutions as described with reference to the figures, a first semiconductor die 14A (a power, IC, semiconductor die, for instance) is arranged at a die pad 12A in a substrate 12 (a leadframe, for instance) comprising electrically conductive leads 12B arranged sidewise of the die pad 12A.

An electrically conductive clip 18 is applied bridge-like between the first semiconductor die 14A arranged at the die pad 12A and at least one lead 12B out of the electrically conductive leads 12B to provide electrical coupling therebetween. The electrically conductive clip 18 is applied onto the first semiconductor die 14A with a first surface of the electrically conductive clip 18 facing the first semiconductor die 14A.

An electrically insulating layer 100 is formed at a second surface of the electrically conductive clip 18 opposite the first surface.

A second semiconductor die 14B (a driver/controller, IC, semiconductor die, for instance) is arranged onto the electrically insulating layer 100 formed at the second surface of the electrically conductive clip 18.

Electrical insulation of the second semiconductor die 14B from the electrically conductive clip 18 is facilitated by the electrically insulating layer 100 formed at the second surface of the electrically conductive clip 18.

The electrically insulating layer 100 may be an additively manufactured layer, that is, an electrically insulating layer 100 formed via additive manufacturing techniques (such as LIFT, for instance).

In one or more embodiments, an adhesive layer DA (a die-attach film, for instance) is provided at a surface of the second semiconductor die 14B. The second semiconductor die 14B is arranged onto the electrically insulating layer 100 formed at the second surface of the electrically conductive clip 18 with the adhesive layer DA in contact with the electrically insulating layer 100.

In one or more embodiments, the electrically insulating layer 100 may be formed with a layer area larger than the die area of the second semiconductor die 14B.

Advantageously, the second semiconductor die 14B may be arranged at a central region of the electrically insulating layer 100 having a layer area larger than the die area of the second semiconductor die 14B; a peripheral region 1000 of the electrically insulating layer 100 around the central region is left uncovered by the second semiconductor die 14B.

In one or more embodiments, the electrically insulating layer 100 may be formed to compensate a warped electrically conductive clip 18. Said otherwise, the second surface of the electrically conductive clip 18 may have a warped shape and the electrically insulating layer 100 may be formed at the second surface of the electrically conductive clip 18 having a warped shape with a varying layer thickness T1, T2 to provide a substantially flat die-mounting surface 100A of the electrically insulating layer 100 (that is, the top/front surface of the electrically insulating layer 100 configured to have the second semiconductor die 14B arranged thereon).

Without prejudice to the underlying principles, the details and embodiments may vary, even significantly, with respect to what has been described by way of example only without departing from the extent of protection.

The claims are an integral part of the technical teaching provided in respect of the embodiments.

The extent of protection is determined by the annexed claims.

1. A method, comprising:
arranging a first semiconductor die at a die pad of a substrate comprising electrically conductive leads arranged sidewise of the die pad;
applying an electrically conductive clip bridge-like between the first semiconductor die arranged at the die pad and at least one lead out of said electrically conductive leads to provide electrical coupling therebetween, wherein the electrically conductive clip is applied onto the first semiconductor die with a first surface of the electrically conductive clip facing the first semiconductor die;
forming an electrically insulating layer at a second surface of the electrically conductive clip opposite said first surface; and
arranging a second semiconductor die on the electrically insulating layer formed at said second surface of the electrically conductive clip, wherein electrical insulation of the second semiconductor die from the electrically conductive clip is facilitated by said electrically insulating layer formed at the second surface of the electrically conductive clip.

2. The method of claim 1, comprising:
providing an adhesive layer at a surface of the second semiconductor die; and
arranging the second semiconductor die on said electrically insulating layer formed at said second surface of the electrically conductive clip with said adhesive layer in contact with the electrically insulating layer.

3. The method of claim 2, wherein the second semiconductor die has a die area and the method comprises forming said electrically insulating layer with a layer area larger than the die area of the second semiconductor die.

4. The method of claim 2, comprising arranging the second semiconductor die at a central region of said electrically insulating layer having a layer area larger than a die area of the second semiconductor die, wherein a peripheral region of the electrically insulating layer around said central region is left uncovered by said second semiconductor die.

5. The method of claim 1, comprising forming the electrically insulating layer at the second surface of the electrically conductive clip via an additive manufacturing technique.

6. The method of claim 5, wherein the additive manufacturing technique is a laser induced forward transfer (LIFT) technique.

7. The method of claim 1, wherein the second surface of the electrically conductive clip has a warped shape, and wherein the method comprises forming said electrically insulating layer at the second surface of the electrically conductive clip having a warped shape with a varying layer thickness to provide a substantially flat die-mounting surface of the electrically insulating layer.

8. The method of claim 1, wherein the electrically insulating layer is made of a flexible polymeric material.

9. A device, comprising:
a first semiconductor die on a die pad of a substrate comprising electrically conductive leads arranged sidewise of the die pad;
an electrically conductive clip extending bridge-like between the first semiconductor die arranged at the die pad and at least one lead out of said electrically conductive leads to provide electrical coupling therebetween, wherein the electrically conductive clip mounts on the first semiconductor die with a first surface of the electrically conductive clip facing the first semiconductor die;
an electrically insulating layer at a second surface of the electrically conductive clip opposite said first surface; and
a second semiconductor die on the electrically insulating layer at said second surface of the electrically conductive clip, wherein electrical insulation of the second semiconductor die from the electrically conductive clip is facilitated by said electrically insulating layer formed at the second surface of the electrically conductive clip.

10. The device of claim 9, further comprising:
an adhesive layer at a surface of the second semiconductor die; and
wherein the second semiconductor die is on said electrically insulating layer formed at said second surface of the electrically conductive clip with said adhesive layer in contact with the electrically insulating layer.

11. The device of claim 10, wherein the second semiconductor die has a die area and wherein said electrically insulating layer has a layer area larger than the die area of the second semiconductor die.

12. The device of claim 10, wherein the second semiconductor die is mounted at a central region of said electrically insulating layer having a layer area larger than a die area of the second semiconductor die, wherein a peripheral region of the electrically insulating layer around said central region is left uncovered by said second semiconductor die.

13. The device of claim 9, wherein the adhesive layer comprises an additive manufacturing electrically insulating layer at the second surface of the electrically conductive clip.

14. The device of claim 9, wherein the second surface of the electrically conductive clip has a warped shape, and wherein said electrically insulating layer at the second surface of the electrically conductive clip with the warped shape has a varying layer thickness that provides a substantially flat die-mounting surface of the electrically insulating layer.

15. The device of claim 9, wherein the electrically insulating layer is made of a flexible polymeric material.
